(19) United States
(12) Patent Application Publication
(10) Pub. No.: US 2026/0114322 A1
(43) Pub. Date: Apr. 23, 2026

(54) ELECTRONIC PACKAGE, ELECTRONIC PACKAGE MODULE AND METHOD FOR FABRICATING THE SAME

(71) Applicant: SILICONWARE PRECISION INDUSTRIES CO., LTD., Taichung City (TW)

(72) Inventors: Shuai-Lin LIU, Taichung City (TW); Wen-Jung TSAI, Taichung City (TW); Yu-Po WANG, Taichung City (TW)

(73) Assignee: SILICONWARE PRECISION INDUSTRIES CO., LTD., Taichung City (TW)

(21) Appl. No.: 19/041,678

(22) Filed: Jan. 30, 2025

(30) Foreign Application Priority Data
Oct. 17, 2024 (TW) 113139554

(51) Int. Cl. H01L 25/16; H01L 21/48; H01L 21/56; H01L 21/683; H01L 23/00; H01L 23/31; H01L 23/498; H01L 23/538

(52) U.S. Cl. CPC H10W 90/00; H10P 72/74; H10W 70/093; H10W 70/611; H10W 70/65; H10W 74/019; H10W 90/401; H10W 72/227; H10W 72/237; H10W 72/877; H10W 74/10; H10W 74/114; H10W 74/15; H10W 90/24; H10W 90/724; H10W 90/734; H10W 90/736

(57) ABSTRACT

An electronic package is provided and includes: a first circuit structure having a first surface, a second surface, and a first circuit layer; an electronic component set including a first electronic component having a first active surface and a first inactive surface, and a second electronic component having a second active surface and a second inactive surface, wherein the first inactive surface of the first electronic component is disposed on the first surface, and the second inactive surface of the second electronic component is offsetly attached to the first active surface; a packaging layer having a first packaging surface and a second packaging surface and covering the electronic component set; a second circuit structure disposed on the first packaging surface and electrically connected to the first circuit layer, the first active surface and the second active surface, respectively; and an optoelectronic component disposed on the second circuit structure.

### BACKGROUND

### 1. Technical Field

The present disclosure relates to a semiconductor device, and more particularly, to an electronic package with a plurality of stacked electronic components and a manufacturing method thereof, and an electronic package module with a plurality of the electronic packages.

### 2. Description of Related Art

With the rise and explosive growth of applications and technologies such as personal computers, Internet, mobile communications, streaming media, online games and artificial intelligence (AI), data transmission technology has also continued to increase the demand for bandwidth, thereby technology using copper wires as transmission medium is increasingly unable to meet the requirements of modern data transmission. As a result, optical communication technology began to replace copper links in large numbers. The semiconductor industry has subsequently developed Co-Packaged Optics (CPO) technology and components for optical communications.

FIG. 1A is a schematic top view of a conventional co-packaged optical module 100; and FIG. 1B is a schematic cross-sectional view of one of the optical engines in FIG. 1A. As shown in FIG. 1A, in the structure of the conventional co-packaged optical module 100, a plurality of optical engines 11 and a semiconductor component 13 (such as a memory module) are integrated on a circuit substrate 12. As shown in FIG. 1B, each of the optical engines 11 includes a plurality of electronic integrated circuit (EIC) chips 111a, 111b, 111c and a photonic integrated circuit chip 112. The photonic integrated circuit chip 112 is used to receive and transmit optical signals. The plurality of electronic integrated circuit chips 111a, 111b, 111c are packaged side by side in a packaging layer 113 and are electrically connected to the photonic integrated circuit chip 112 for conversion of optical signals and electronic signals. However, disposing the plurality of electronic integrated circuit chips 111a, 111b, 111c side by side requires a larger area, resulting in a great limitation on the number of the optical engines 11 that can be connected to the conventional co-packaged optical module 100. For example, each side of the co-packaged optical module 100 shown in FIG. 1A can only accommodate two optical engines 11 and cannot be added more optical engines 11, resulting in a limitation in amount of data/information that the co-packaged optical module 100 can receive and transmit per unit time; however, if the area of the circuit substrate 12 in the co-packaged optical module 100 is increased to accommodate more optical engines 11, the requirement for miniaturization cannot be achieved.

Therefore, how to overcome the aforementioned problems of the prior art has become an urgent issue to be solved.

### SUMMARY

In view of the aforementioned shortcomings of the prior art, the present disclosure provides an electronic package, which comprises: a first circuit structure having a first surface, a second surface opposite to the first surface, and at least one first circuit layer; an electronic component set including a first electronic component and a second electronic component, wherein the first electronic component has a first active surface and a first inactive surface opposite to the first active surface, the first inactive surface of the first electronic component is attached to the first surface of the first circuit structure, and the second electronic component has a second active surface and a second inactive surface opposite to the second active surface, the second inactive surface of the second electronic component is offsetly attached to the first active surface of the first electronic component in a manner that a part of the first active surface is exposed from a side of the second electronic component; a packaging layer covering the electronic component set and defined with a first packaging surface and a second packaging surface opposite to the first packaging surface, and the second packaging surface is attached to the first surface of the first circuit structure; a second circuit structure disposed on the first packaging surface of the packaging layer and having at least one second circuit layer, wherein the second circuit layer of the second circuit structure is electrically connected to the first circuit layer of the first circuit structure, the first active surface of the first electronic component and the second active surface of the second electronic component, respectively; and an optoelectronic component disposed on a side of the second circuit structure that is not in contact with the packaging layer, wherein the optoelectronic component is electrically connected to the second circuit structure.

The present disclosure further provides an electronic package module, which comprises: a carrier structure having a carrying surface; a chip disposed on the carrying surface of the carrier structure and electrically connected to the carrier structure; and a plurality of electronic packages disposed on the carrying surface of the carrier structure and surrounding the chip, and each of the plurality of electronic packages comprising: a first circuit structure having a first surface, a second surface opposite to the first surface, and at least one first circuit layer, wherein the second surface of the first circuit structure is electrically connected to the carrier structure; an electronic component set including a first electronic component and a second electronic component, wherein the first electronic component has a first active surface and a first inactive surface opposite to the first active surface, the first inactive surface of the first electronic component is attached to the first surface of the first circuit structure, and the second electronic component has a second active surface and a second inactive surface opposite to the second active surface, the second inactive surface of the second electronic component is offsetly attached to the first active surface of the first electronic component in a manner that a part of the first active surface is exposed from a side of the second electronic component; a packaging layer covering the electronic component set and defined with a first packaging surface and a second packaging surface opposite to the first packaging surface, and the second packaging surface is attached to the first surface of the first circuit structure; a second circuit structure disposed on the first packaging surface of the packaging layer and having at least one second circuit layer, wherein the second circuit layer of the second circuit structure is electrically connected to the first circuit layer of the first circuit structure, the first active surface of the first electronic component and the second active surface of the second electronic component, respectively; and an optoelectronic component disposed on a side of the second circuit structure that is not in contact with the packaging layer, wherein the optoelectronic component is electrically connected to the second circuit structure.

The present disclosure also provides a method of fabricating an electronic package, the method comprises: forming a first circuit structure on a carrier, wherein the first circuit structure has a first surface, a second surface opposite to the first surface, and at least one first circuit layer, wherein the second surface of the first circuit structure is attached to the carrier; disposing an electronic component set on the first surface of the first circuit structure, wherein the electronic component set includes a first electronic component and a second electronic component, wherein the first electronic component has a first active surface and a first inactive surface opposite to the first active surface, and the first inactive surface of the first electronic component is attached to the first surface of the first circuit structure, and the second electronic component has a second active surface and a second inactive surface opposite to the second active surface, the second inactive surface of the second electronic component is offsetly attached to the first active surface of the first electronic component in a manner that a part of the first active surface is exposed from a side of the second electronic component; forming a packaging layer to cover the electronic component set, wherein the packaging layer is defined with a first packaging surface and a second packaging surface opposite to the first packaging surface, and the second packaging surface is attached to the first circuit structure; forming a second circuit structure on the first packaging surface of the packaging layer, wherein the second circuit structure includes at least one second circuit layer, and the second circuit layer of the second circuit structure is electrically connected to the first circuit layer of the first circuit structure, the first active surface of the first electronic component and the second active surface of the second electronic component, respectively; disposing an optoelectronic component on a side of the second circuit structure that is not in contact with the packaging layer, wherein the optoelectronic component is electrically connected to the second circuit structure; and removing the carrier.

In the aforementioned electronic package, method and electronic package module, the present disclosure further comprises a plurality of penetrating conductive elements disposed on the first surface of the first circuit structure, a plurality of first conductive elements disposed on the part of the first active surface exposed from said side of the second electronic component, and a plurality of second conductive elements disposed on the second active surface, wherein the second circuit layer is electrically connected to the first circuit layer, the first active surface and the second active surface via the plurality of penetrating conductive elements, the plurality of first conductive elements and the plurality of second conductive elements, respectively.

In the aforementioned electronic package, method and electronic package module, the first electronic component and the second electronic component are electronic integrated circuits.

In the aforementioned electronic package, method and electronic package module, the optoelectronic component is a photonic integrated circuit.

In the aforementioned electronic package, method and electronic package module, the first circuit structure includes at least one redistribution layer.

In the aforementioned electronic package, method and electronic package module, the second circuit structure includes at least one redistribution layer.

In the aforementioned electronic package, method and electronic package module, the electronic component set further comprises a third electronic component having a third active surface and a third inactive surface opposite to the third active surface, wherein the third inactive surface of the third electronic component is offsetly attached to the second active surface of the second electronic component in a manner that a part of the second active surface is exposed from a side of the third electronic component, the plurality of second conductive elements are disposed on the part of the second active surface exposed from said side of the third electronic component, and a plurality of third conductive elements are disposed on the third active surface and electrically connected to the at least one second circuit layer.

In the aforementioned electronic package, method and electronic package module, the present disclosure further comprises a plurality of conductive connectors disposed on the second surface of the first circuit structure, wherein the plurality of conductive connectors are electrically connected to the first circuit layer, respectively.

In the aforementioned electronic package, method and electronic package module, the present disclosure further comprises disposing a plurality of the electronic packages on a carrying surface of a carrier structure, wherein the plurality of electronic packages surround a chip, and each of the plurality of electronic packages is electrically connected to the carrier structure via the plurality of conductive connectors.

In the aforementioned electronic package, method and electronic package module, the chip is a switch die.

In the aforementioned electronic package, method and electronic package module, a plurality of the electronic packages are disposed on each side of the carrier structure, respectively.

It can be seen from the above that, in the electronic package and the manufacturing method thereof and the electronic package module of the present disclosure, the first electronic component, the second electronic component and the third electronic component are stacked in the electronic package (which is used as the optical engine) so as to greatly reduce the area occupied by the electronic package, so that the number of the optical engines that can be accommodated in the co-packaged optical electronic module can be increased, and the data transmission capacity of the electronic module can be improved effectively.

### BRIEF DESCRIPTION OF THE DRAWINGS

FIG. 1A is a schematic top view showing a conventional co-packaged optical module.

FIG. 1B is a schematic cross-sectional view showing one of optical engines in FIG. 1A.

FIG. 2A to FIG. 2E-1 are schematic cross-sectional views showing a first embodiment of the manufacturing method of an electronic package of the present disclosure.

FIG. 2E-2 is a schematic top view showing an embodiment of an electronic package module of the present disclosure.

FIG. 3A to FIG. 3E are schematic cross-sectional views showing a second embodiment of the manufacturing method of an electronic package of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

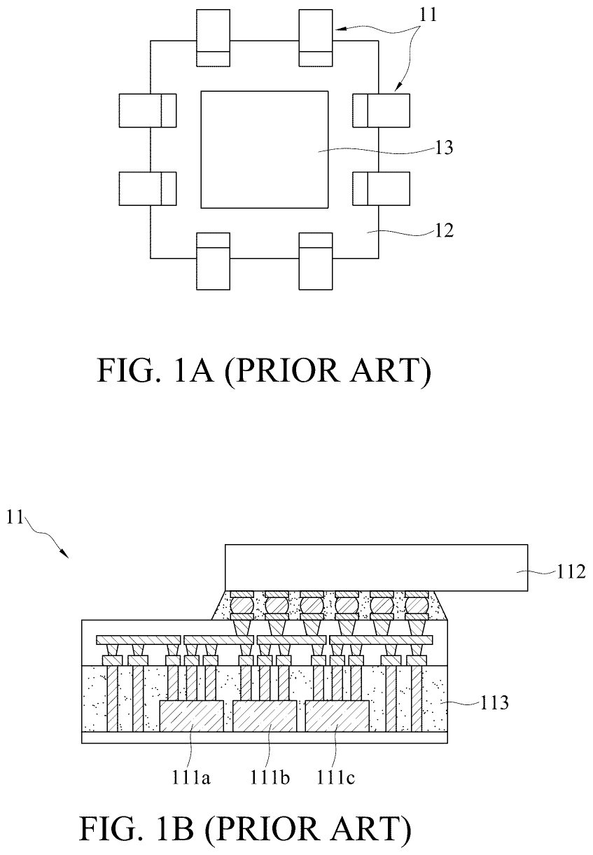

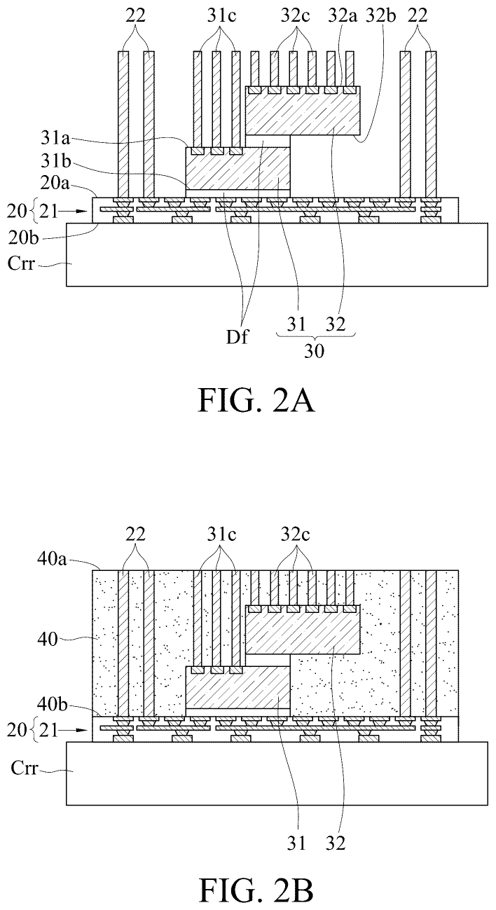

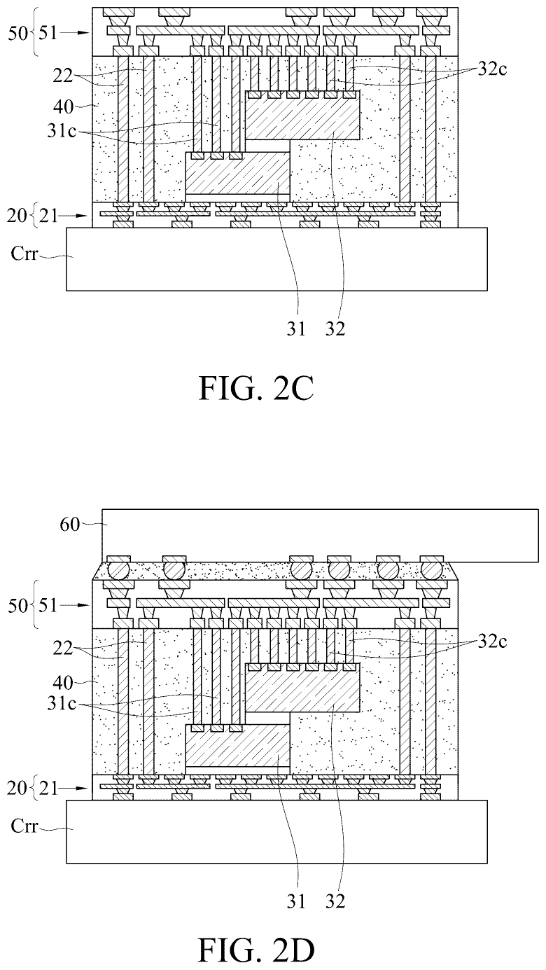

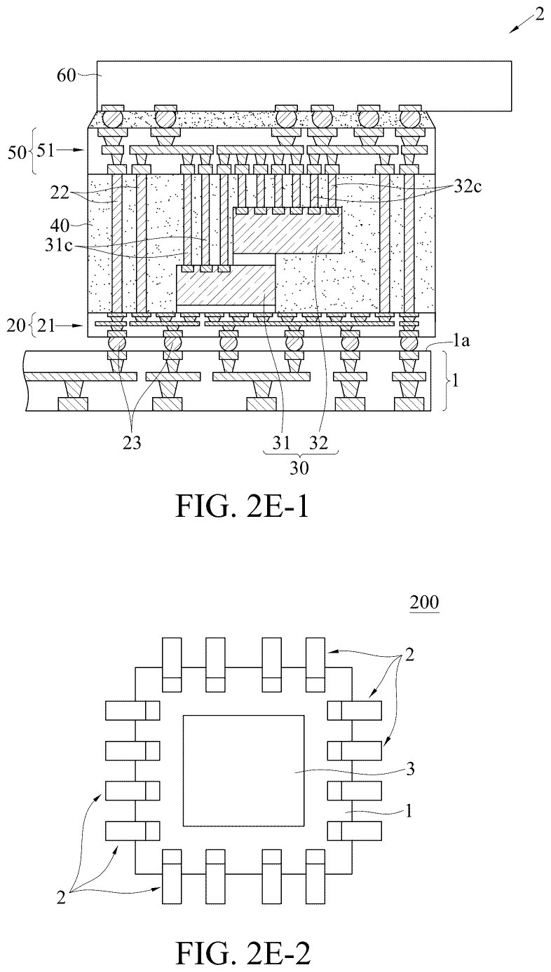

FIG. 2A to FIG. 2E-1 are schematic cross-sectional views showing a first embodiment of the manufacturing method of an electronic package 2 of the present disclosure.

As shown in FIG. 2A, a carrier Crr is provided at first, and the carrier Crr can be a board made of semiconductor material such as silicon or glass, or any other suitable material.

Then, a first circuit structure 20 is formed on the carrier Crr. The first circuit structure 20 has a first surface 20a and a second surface 20b opposite to the first surface 20a, and the second surface 20b is attached to the carrier Crr. The first circuit structure 20 includes at least one first circuit layer 21. In some embodiments, the first circuit structure 20 can include at least one redistribution layer (RDL).

Then, an electronic component set 30 is disposed on the first surface 20a of the first circuit structure 20. The electronic component set 30 includes a first electronic component 31 and a second electronic component 32. The first electronic component 31 has a first active surface 31a and a first inactive surface 31b opposite to the first active surface 31a, and the first inactive surface 31b of the first electronic component 31 is attached to the first surface 20a of the first circuit structure 20. In some embodiments, a die attach film (DAF) Df is formed on the first inactive surface 31b, and the first inactive surface 31b of the first electronic component 31 is attached to the first surface 20a of the first circuit structure 20 via the die attach film Df.

The first electronic component 31 can be an active element, such as a semiconductor chip, or a passive element, such as a resistor, a capacitor, or an inductor. In an embodiment, the first electronic component 31 is an electronic integrated circuit (EIC) as an example.

The second electronic component 32 has a second active surface 32a and a second inactive surface 32b opposite to the second active surface 32a, and the second inactive surface 32b of the second electronic component 32 is offsetly attached to a side of the first active surface 31a of the first electronic component 31 in a manner that a part of the first active surface 31a is exposed from a side of the second electronic component 32 (e.g., exposed from an outer side of the second electronic component 32). In some embodiments, the second electronic component 32 can be adhesively fixed on the first active surface 31a of the first electronic component 31 via a die attach film Df. The second electronic component 32 can also be an active element or a passive element, and in an embodiment, the second electronic component 32 is an electronic integrated circuit (EIC).

Moreover, a plurality of first conductive elements 31c are pre-set on said part of the first active surface 31a of the first electronic component 31 exposed from said side of the second electronic component 32, and a plurality of second conductive elements 32c are also pre-set on the second active surface 32a of the second electronic component 32. Meanwhile, a plurality of penetrating conductive elements 22 electrically connected to the first circuit layer 21 in the first circuit structure 20 are disposed on the first surface 20a of the first circuit structure 20 and are outside of the electronic component set 30. Each of the first conductive elements 31c, each of the second conductive elements 32c and each of the penetrating conductive elements 22 can be a conductive bump, such as a copper pillar or a stud conductive element, but the present disclosure is not limited to as such. In addition, top ends of the plurality of penetrating conductive elements 22, top ends of the plurality of first conductive elements 31c and top ends of the plurality of second conductive elements 32c are all located at the same height above the first surface 20a of the first circuit structure 20.

As shown in FIG. 2B, a packaging layer 40 is formed on the first surface 20a of the first circuit structure 20 to encapsulate the electronic component set 30, the plurality of penetrating conductive elements 22, the plurality of first conductive elements 31c and the plurality of second conductive elements 32c, etc. The packaging layer 40 is made of, for example, a dry film, an epoxy molding colloid, or an epoxy molding compound. The packaging layer 40 is defined with a first packaging surface 40a and a second packaging surface 40b opposite to the first packaging surface 40a. The second packaging surface 40b is attached to the first surface 20a of the first circuit structure 20. The top ends of the plurality of penetrating conductive elements 22, the top ends of the plurality of first conductive elements 31c and the top ends of the plurality of second conductive elements 32c can be exposed from the first packaging surface 40a via grinding.

As shown in FIG. 2C, a second circuit structure 50 is then formed on the first packaging surface 40a of the packaging layer 40. The second circuit structure 50 includes at least one second circuit layer 51. The second circuit layer 51 is electrically connected to the first circuit layer 21 of the first circuit structure 20, the first active surface 31a of the first electronic component 31 and the second active surface 32a of the second electronic component 32 via the plurality of penetrating conductive elements 22, the plurality of first conductive elements 31c and the plurality of second conductive elements 32c, respectively. In some embodiments, the second circuit structure 50 includes at least one redistribution layer (RDL).

As shown in FIG. 2D, an optoelectronic component 60 is provided and disposed on a side of the second circuit structure 50 that is not in contact with the packaging layer 40, and the optoelectronic component 60 is electrically connected to the second circuit structure 50. In an embodiment, the optoelectronic component 60 is, for example, a photonic integrated circuit (PIC).

As shown in FIG. 2E-1, the carrier Crr is removed to obtain the electronic package 2 of the present disclosure.

In some modified embodiments, after the carrier Crr is removed, as shown in FIG. 2E-1, a plurality of conductive connectors 23 electrically connected to the first circuit layer 21 respectively are further disposed on the second surface 20b of the first circuit structure 20. Each of the conductive connectors 23 can be a conductive bump, such as a solder ball illustrated in an embodiment, so that when the electronic package 2 is applied, the plurality of conductive connectors 23 can be electrically connected to external circuits.

Furthermore, the manufacturing method of the present disclosure further includes that a plurality of the electronic packages 2 manufactured by the aforementioned processes are disposed on a carrying surface 1a of a carrier structure 1. Only one electronic package 2 and a part of the carrier structure 1 are shown in FIG. 2E-1. As shown in FIG. 2E-2, a complete schematic top view of an electronic package module 200 is shown. As shown in FIG. 2E-1 and FIG. 2E-2, the plurality of electronic packages 2 are disposed around a chip 3 that is also disposed on the carrying surface 1a. The second surface of the first circuit structure of each of the electronic packages is electrically connected to the carrier structure. The carrier structure 1 is, for example, a multi-layer circuit board containing multi-layer circuits, but the present disclosure is not limited to as such. The chip 3 is, for example, a switch die/chip; however, the chip 3 can also be a chip in other types, and the type of the chip 3 depends on the requirements of the overall circuit design, and there is no limitation to the type of the chip 3 in the present disclosure.

Since the electronic package 2 provided in the embodiment includes a photonic integrated circuit as the optoelectronic component 60 and a plurality of electronic integrated circuits electrically connected to the photonic integrated circuit, and the photonic integrated circuit can be used to connect to external optical fibers (not shown) to transmit and receive optical signals. Therefore, the plurality of electronic packages 2 can be used as optical engines (OE), and the plurality of electronic packages 2, the carrier structure 1 and the chip 3 constitute the electronic package module 200 in a Co-Packaged Optics form.

In an embodiment, in which the bottom of each of the electronic packages 2 has the conductive connectors 23, when the plurality of electronic packages 2 are disposed on the carrying surface 1a of the carrier structure 1, each of the electronic packages 2 is electrically connected to the carrier structure 1 via the plurality of conductive connectors 23.

Since the first electronic component 31 and the second electronic component 32 in the electronic package 2 manufactured by the manufacturing method of the present disclosure are disposed in the electronic package 2 in a stacked manner, the area occupied by the electronic package 2 can thus be greatly reduced, such that each side of the carrier structure 1 can accommodate more electronic packages 2 as optical engines. In an embodiment, four electronic packages 2 (optical engines) are disposed on each side of the carrier structure 1 of the electronic package module 200 in a Co-Packaged Optics form as an example.

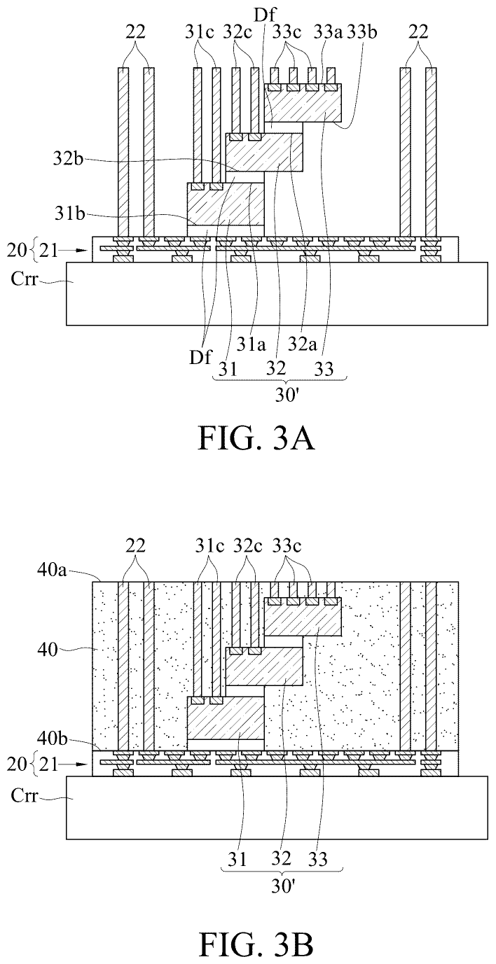

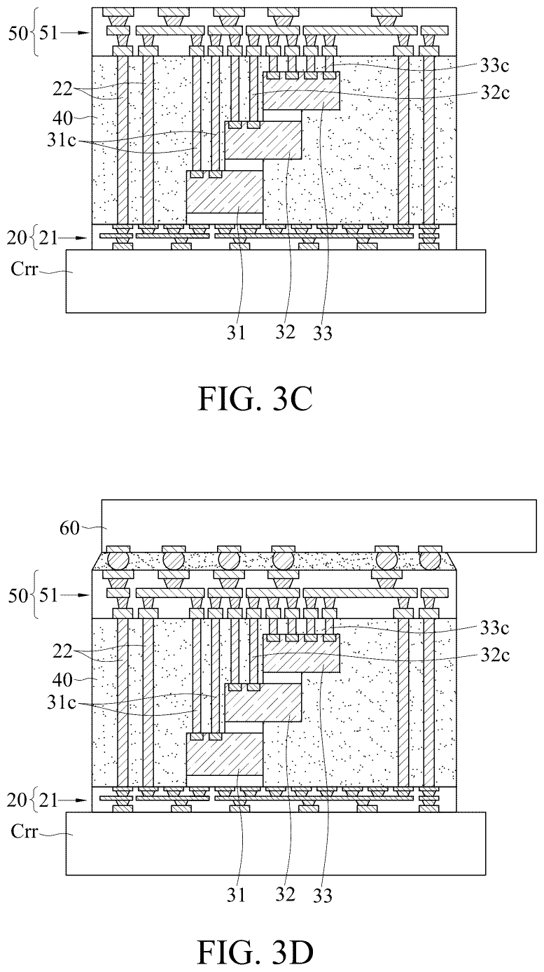

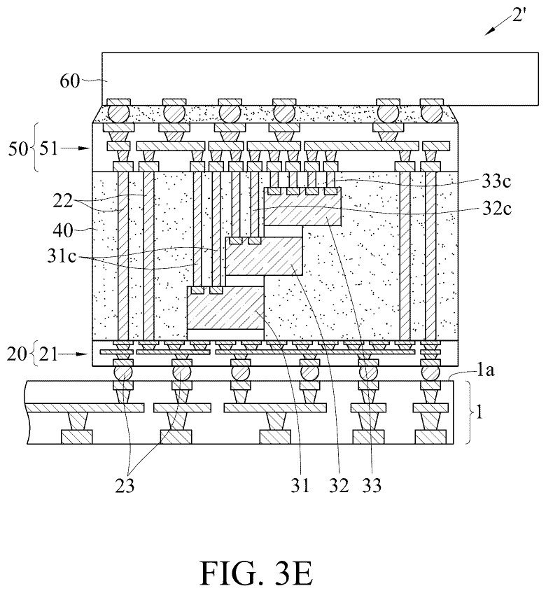

FIG. 3A to FIG. 3E are schematic cross-sectional views showing a second embodiment of the manufacturing method of an electronic package 2′ of the present disclosure. The main difference between the second embodiment and the first embodiment is that the electronic component set 30′ of the electronic package 2′ in the second embodiment further includes a third electronic component 33 having a third active surface 33a and a third inactive surface 33b opposite to the third active surface 33a. The third inactive surface 33b of the third electronic component 33 is offsetly attached to the second active surface 32a of the second electronic component 32 in a manner that a part of the second active surface 32a is exposed from a side of the third electronic component 33, and the plurality of second conductive elements 32c are disposed on said part of the second active surface 32a exposed from said side of the third electronic component 33. In some embodiments, the third electronic component 33 is attached to another part of the second active surface 32a of the second electronic component 32 via a die attach film Df (which is disposed on the third inactive surface 33b).

Similar to the first electronic component 31 and the second electronic component 32, a plurality of third conductive elements 33c are pre-set on the third active surface 33a of the third electronic component 33. As same as the second conductive elements 32c, the third conductive elements 33c can also be conductive bumps or stud conductive elements, and the present disclosure is not limited to as such.

In addition to the aforementioned parts related to the third electronic component 33 and/or the third conductive elements 33c, the remaining parts of the manufacturing method of the second embodiment (including forming the packaging layer 40 and the second circuit structure 50, and connecting to the optoelectronic component 60) are the same as those in the aforementioned first embodiment, so they will not be described again here.

The present disclosure further provides an electronic package 2, the electronic package 2 comprises: a first circuit structure 20 having a first surface 20a, a second surface 20b opposite to the first surface 20a, and at least one first circuit layer 21; an electronic component set 30 having a first electronic component 31 and a second electronic component 32, wherein the first electronic component 31 has a first active surface 31a and a first inactive surface 31b opposite to the first active surface 31a, and the first inactive surface 31b of the first electronic component 31 is attached to the first surface 20a of the first circuit structure 20, wherein the second electronic component 32 has a second active surface 32a and a second inactive surface 32b opposite to the second active surface 32a, and the second inactive surface 32b of the second electronic component 32 is offsetly attached to the first active surface 31a of the first electronic component 31 in a manner that a part of the first active surface 31a is exposed from a side of the second electronic component 32; a packaging layer 40 covering the electronic component set 30 and defined with a first packaging surface 40a and a second packaging surface 40b opposite to the first packaging surface 40a, wherein the second packaging surface 40b is attached to the first surface 20a of the first circuit structure 20; a second circuit structure 50 disposed on the first packaging surface 40a of the packaging layer 40 and having at least one second circuit layer 51, wherein the second circuit layer 51 of the second circuit structure 50 is electrically connected to the first circuit layer 21 of the first circuit structure 20, the first active surface 31a of the first electronic component 31 and the second active surface 32a of the second electronic component 32, respectively; and an optoelectronic component 60 disposed on a side of the second circuit structure 50 that is not in contact with the packaging layer 40, wherein the optoelectronic component 60 is electrically connected to the second circuit structure 50.

In some embodiments, a plurality of penetrating conductive elements 22 are disposed on the first surface 20a of the first circuit structure 20, a plurality of first conductive elements 31c are disposed on said part of the first active surface 31a that is exposed from said side of the second electronic component 32, a plurality of second conductive elements 32c are disposed on the second active surface 32a, and the second circuit layer 51 is electrically connected to the first circuit layer 21, the first active surface 31a and the second active surface 32a via the plurality of penetrating conductive elements 22, the plurality of first conductive elements 31c and the plurality of second conductive elements 32c, respectively.

In some embodiments, the first electronic component 31 and the second electronic component 32 are electronic integrated circuits.

In some embodiments, the optoelectronic component 60 is a photonic integrated circuit.

In some embodiments, the first circuit structure 20 includes at least one redistribution layer.

In some embodiments, the second circuit structure 50 includes at least one redistribution layer.

In a modified embodiment, the electronic component set 30′ further comprises a third electronic component 33, the third electronic component 33 has a third active surface 33a and a third inactive surface 33b opposite to the third active surface 33a, and the third inactive surface 33b of the third electronic component 33 is offsetly attached to the second active surface 32a of the second electronic component 32 in a manner that a part of the second active surface 32a is exposed from a side of the third electronic component 33, and the plurality of second conductive elements 32c are disposed on said part of the second active surface 32a that is exposed from said side of the third electronic component 33, and a plurality of third conductive elements 33c electrically connected to the second circuit layer 51 are disposed on the third active surface 33a. In an embodiment, the third electronic component 33 is also an electronic integrated circuit. A modified electronic package 2′ is formed by adopting the electronic component set 30′ in a modified aspect.

In some embodiments, a plurality of conductive connectors 23 are disposed on the second surface 20b of the first circuit structure 20, and the plurality of conductive connectors 23 are electrically connected to the first circuit layer 21, respectively.

The present disclosure further provides an electronic package module 200, the electronic package module 200 includes: a carrier structure 1 having a carrying surface 1a; a chip 3 disposed on the carrying surface 1a of the carrier structure 1 and electrically connected to the carrier structure 1; and a plurality of the electronic packages 2 (or the electronic packages 2') disposed on the carrying surface 1a of the carrier structure 1 and surrounding the chip 3. Since the structure of each of the electronic packages 2, 2′ has been described in detail in the aforementioned content, it will not be described again here.

In some embodiments, the plurality of conductive connectors 23 are further disposed on the second surface 20b of the first circuit structure 20, and each of the electronic packages 2, 2′ is electrically connected to the carrier structure 1 via the plurality of conductive connectors 23.

In some embodiments, the chip 3 is a switch die.

In some embodiments, a plurality of the electronic packages 2, 2′ are disposed on each side of the carrier structure 1, respectively.

To sum up, in the electronic package and the manufacturing method thereof and the electronic package module of the present disclosure, when the first electronic component, the second electronic component and/or the third electronic component are being stacked, the first active surface of the first electronic component, the second active surface of the second electronic component and the third active surface of the third electronic component face the interior of the electronic package, and a part of the first active surface, a part of the second active surface and the third active surface are exposed to form a stepped structure, and the plurality of first conductive elements, the plurality of second conductive elements and the plurality of third conductive elements are pre-set between the second circuit structure and said part of the first active surface, said part of the second active surface and the third active surface exposed towards the interior of the electronic package, so as to save the area occupied by the electronic package on a plane parallel to the bottom surface of the electronic package, such that the number of optical engines that can be accommodated in a co-packaged optical electronic module can be increased, and the data transmission capacity of the electronic module can be improved effectively.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a first circuit structure having a first surface, a second surface opposite to the first surface, and a first circuit layer;
an electronic component set including a first electronic component and a second electronic component, wherein the first electronic component has a first active surface and a first inactive surface opposite to the first active surface, the first inactive surface of the first electronic component is attached to the first surface of the first circuit structure, and the second electronic component has a second active surface and a second inactive surface opposite to the second active surface, the second inactive surface of the second electronic component is offsetly attached to the first active surface of the first electronic component in a manner that a part of the first active surface is exposed from the second electronic component;
a packaging layer covering the electronic component set and defined with a first packaging surface and a second packaging surface opposite to the first packaging surface, wherein the second packaging surface is attached to the first surface of the first circuit structure;
a second circuit structure disposed on the first packaging surface of the packaging layer and having a second circuit layer, wherein the second circuit layer of the second circuit structure is electrically connected to the first circuit layer of the first circuit structure, the first active surface of the first electronic component and the second active surface of the second electronic component, respectively; and
an optoelectronic component disposed on a side of the second circuit structure that is not in contact with the packaging layer, wherein the optoelectronic component is electrically connected to the second circuit structure.

2. The electronic package of claim 1, further comprising a plurality of penetrating conductive elements disposed on the first surface of the first circuit structure, a plurality of first conductive elements disposed on the part of the first active surface exposed from a side of the second electronic component, and a plurality of second conductive elements disposed on the second active surface, wherein the second circuit layer is electrically connected to the first circuit layer, the first active surface and the second active surface via the plurality of penetrating conductive elements, the plurality of first conductive elements and the plurality of second conductive elements, respectively.

3. The electronic package of claim 1, wherein the first electronic component and the second electronic component are electronic integrated circuits.

4. The electronic package of claim 1, wherein the optoelectronic component is a photonic integrated circuit.

5. The electronic package of claim 1, wherein the first circuit structure includes a redistribution layer.

6. The electronic package of claim 1, wherein the second circuit structure includes a redistribution layer.

7. The electronic package of claim 1, wherein the electronic component set further comprises a third electronic component having a third active surface and a third inactive surface opposite to the third active surface, wherein the third inactive surface of the third electronic component is offsetly attached to the second active surface of the second electronic component in a manner that a part of the second active surface is exposed from the third electronic component, and a plurality of third conductive elements are disposed on the third active surface and electrically connected to the second circuit layer.

8. The electronic package of claim 1, further comprising a plurality of conductive connectors disposed on the second surface of the first circuit structure, wherein the plurality of conductive connectors are electrically connected to the first circuit layer, respectively.

9. An electronic package module, comprising:
a carrier structure having a carrying surface;
a chip disposed on the carrying surface of the carrier structure and electrically connected to the carrier structure; and
a plurality of electronic packages disposed on the carrying surface of the carrier structure and surrounding the chip, and each of the plurality of electronic packages comprising:
a first circuit structure having a first surface, a second surface opposite to the first surface, and a first circuit layer, wherein the second surface of the first circuit structure is electrically connected to the carrier structure;
an electronic component set including a first electronic component and a second electronic component, wherein the first electronic component has a first active surface and a first inactive surface opposite to the first active surface, the first inactive surface of the first electronic component is attached to the first surface of the first circuit structure, and the second electronic component has a second active surface and a second inactive surface opposite to the second active surface, the second inactive surface of the second electronic component offsetly attached to the first active surface of the first electronic component in a manner that a part of the first active surface is exposed from the second electronic component;
a packaging layer covering the electronic component set and defined with a first packaging surface and a second packaging surface opposite to the first packaging surface, wherein the second packaging surface is attached to the first surface of the first circuit structure;
a second circuit structure disposed on the first packaging surface of the packaging layer and having a second circuit layer, wherein the second circuit layer of the second circuit structure is electrically connected to the first circuit layer of the first circuit structure, the first active surface of the first electronic component and the second active surface of the second electronic component, respectively; and
an optoelectronic component disposed on a side of the second circuit structure that is not in contact with the packaging layer, wherein the optoelectronic component is electrically connected to the second circuit structure.

10. The electronic package module of claim 9, further comprising a plurality of penetrating conductive elements disposed on the first surface of the first circuit structure, a plurality of first conductive elements disposed on the part of the first active surface exposed from a side of the second electronic component, and a plurality of second conductive elements disposed on the second active surface, wherein the second circuit layer is electrically connected to the first circuit layer, the first active surface and the second active surface via the plurality of penetrating conductive elements, the plurality of first conductive elements and the plurality of second conductive elements, respectively.

11. The electronic package module of claim 9, wherein the first electronic component and the second electronic component are electronic integrated circuits.

12. The electronic package module of claim 9, wherein the optoelectronic component is a photonic integrated circuit.

13. The electronic package module of claim 9, wherein the first circuit structure includes a redistribution layer.

14. The electronic package module of claim 9, wherein the second circuit structure includes a redistribution layer.

15. The electronic package module of claim 9, wherein the electronic component set further comprises a third electronic component having a third active surface and a third inactive surface opposite to the third active surface, wherein the third inactive surface of the third electronic component is offsetly attached to the second active surface of the second electronic component in a manner that a part of the second active surface is exposed from the third electronic component, and a plurality of third conductive elements are disposed on the third active surface and electrically connected to the second circuit layer.

16. The electronic package module of claim 9, further comprising a plurality of conductive connectors disposed on the second surface of the first circuit structure, wherein each of the plurality of electronic packages is electrically connected to the carrier structure via the plurality of conductive connectors.

17. The electronic package module of claim 9, wherein the chip is a switch die.

18. The electronic package module of claim 9, wherein a plurality of the electronic packages are disposed on each side of the carrier structure, respectively.

19. A method of fabricating an electronic package, comprising:
forming a first circuit structure on a carrier, wherein the first circuit structure has a first surface, a second surface opposite to the first surface, and a first circuit layer, wherein the second surface of the first circuit structure is attached to the carrier;
disposing an electronic component set on the first surface of the first circuit structure, wherein the electronic component set includes a first electronic component and a second electronic component, wherein the first electronic component has a first active surface and a first inactive surface opposite to the first active surface, and the first inactive surface of the first electronic component is attached to the first surface of the first circuit structure, and the second electronic component has a second active surface and a second inactive surface opposite to the second active surface, the second inactive surface of the second electronic component is offsetly attached to the first active surface of the first electronic component in a manner that a part of the first active surface is exposed from the second electronic component;
forming a packaging layer to cover the electronic component set, wherein the packaging layer is defined with a first packaging surface and a second packaging surface opposite to the first packaging surface, and the second packaging surface is attached to the first circuit structure;
forming a second circuit structure on the first packaging surface of the packaging layer, wherein the second circuit structure includes a second circuit layer, and the second circuit layer of the second circuit structure is electrically connected to the first circuit layer of the first circuit structure, the first active surface of the first electronic component and the second active surface of the second electronic component, respectively;
disposing an optoelectronic component on a side of the second circuit structure that is not in contact with the packaging layer, wherein the optoelectronic component is electrically connected to the second circuit structure; and
removing the carrier.

20. The method of claim 19, wherein a plurality of penetrating conductive elements are disposed on the first surface of the first circuit structure, a plurality of first conductive elements are disposed on the part of the first active surface, the second electronic component is offsetly attached to another part of the first active surface where the plurality of first conductive elements are not disposed, and a plurality of second conductive elements are disposed on the second active surface, wherein an end of each of the plurality of first conductive elements and an end of each of the plurality of second conductive elements are exposed from the first packaging surface, and the second circuit layer is electrically connected to the first circuit layer, the first active surface and the second active surface via the plurality of penetrating conductive elements, the plurality of first conductive elements and the plurality of second conductive elements, respectively.

21. The method of claim 19, wherein the first electronic component and the second electronic component are electronic integrated circuits.

22. The method of claim 19, wherein the optoelectronic component is a photonic integrated circuit.

23. The method of claim 19, wherein the first circuit structure includes a redistribution layer.

24. The method of claim 19, wherein the second circuit structure includes a redistribution layer.

25. The method of claim 19, wherein the electronic component set further comprises a third electronic component having a third active surface and a third inactive surface opposite to the third active surface, wherein the third inactive surface of the third electronic component is offsetly attached to the second active surface of the second electronic component in a manner that a part of the second active surface is exposed from the third electronic component, and a plurality of third conductive elements are disposed on the third active surface and electrically connected to the second circuit layer.

26. The method of claim 19, further comprising forming a plurality of conductive connectors on the second surface of the first circuit structure, wherein the plurality of conductive connectors are electrically connected to the first circuit layer, respectively.

27. The method of claim 26, further comprising disposing a plurality of the electronic packages on a carrying surface of a carrier structure, wherein the plurality of electronic packages surround a chip, and each of the plurality of electronic packages is electrically connected to the carrier structure via the plurality of conductive connectors.
